(19) United States
(12) Patent Application Publication
(10) Pub. No.: US 2007/0289775 A1
(43) Pub. Date: Dec. 20, 2007

(54) RFID SHIELDING DEVICES

(76) Inventors: Kevin L. Potts, Mesquite, TX (US); Donald Ryan Shore, Minnetonka, MN (US); David Bryan Wood JR., The Colony, TX (US)

Correspondence Address: Michael A. O'Neil;Michael A. O'Neil, P.C., Suite 820, 5949 Sherry Lane, Dallas, TX, 75225, US

(21) Appl. No.: 11/849,689

(22) Filed: Sep. 4, 2007

Related U.S. Application Data
(63) Continuation-in-part of application No. 11/464,624, filed on Aug. 15, 2006.
(60) Provisional application No. 60/708,578, filed on Aug. 16, 2005.

(51) Int. Cl. H05K 9/00

(52) U.S. Cl. 174/350

(57) ABSTRACT

Unauthorized electronic access to RFID devices embedded in credit cards, personal identification cards, and other cards is prevented by providing wallets, purses, card holders, and other card receiving devices with layers of electromagnetic shielding material which substantially surround cards having RFID devices embedded therein.

### CROSS-REFERENCE TO RELATED APPLICATIONS

This application is a continuation-in-part patent application of application Ser. No. 11/464,624 filed Aug. 15, 2006, currently pending, the entire content of which is Incorporated herein by reference; which claims priority based on provisional patent application Ser. No. 60/708,578 filed Aug. 6, 2005, the entire content of which is incorporated herein by reference.

### TECHNICAL FIELD

This invention relates generally to shielding of REID devices, and more particularly to shielding devices for preventing unauthorized electronic access to personal identification cards and credit cards.

### BACKGROUND AND SUMMARY OF THE INVENTION

Radio Frequency Identification technologies, commonly referred to as REID, utilize electronic signals to identify people and objects. Each RFID system comprises at least one microchip and an antenna, together referred to as an RF ID transponder or tag, and at least one reader. The antenna enables the chip to electronically transmit identification data to the reader. The reader receives and converts the radio waves into digital information for further processing.

RFID systems are used in numerous industries, the most common being use of RFID systems for asset tracking purposes. Active RFID tags have their own transmitter and power source and are therefore used for tracking larger objects across greater distances. Passive RFID tags do not have either a power source or an antenna. Instead they simply reflect waves back to a reader associated with the transmission a of an electronic signal. Passive tags are therefore more limited in range. Examples of passive tag systems include tollbooth applications enabling a transponder on a vehicle to reflect a signal to a reader in the tollbooth and inventory tracking systems in retail stores that track inventory movement within the store and prevent theft of items from the store.

More recently RFID systems have been implemented into touchless express nay systems whereby payment can be made by simply waving a credit card or keyfob in front of a reader. Although highly convenient, express pay systems incorporate the inherent danger that the associated account will be charged by accident or possibly charged without the owner's knowledge. Further, RFID devices are proposed for integration into personal identification cards whereby a reader will be able to detect the presence of a person within its range. Simply containing an RFID tag device in a wallet, pocket, or handbag does not prevent detection of information stored in the RFID device. What is needed is an apparatus protecting RFID devices against unauthorized electronic access.

The present invention comprises RFID shielding devices which overcome the foregoing and other difficulties which have long since characterized the prior art. In accordance with the broader aspects of the invention RFID shielding devices comprise electromagnetic shielding which prevents electronic access to REID devices enclosed therein.

In accordance with a specific embodiment of the invention a shielding pouch includes upper and lower surfaces each comprising a textile material having electromagnetic shielding incorporated therein. The upper and lower surfaces are secured together thereby forming a compartment therebetween with an opening at one end thereof for receiving RFID equipped articles therein. The opening may comprise closure means for maintaining the security of the items stored within the compartment.

The invention further comprises the incorporation of one or more layers of electromagnetic shielding material into wallets, purses, passport receiving portfolios, and other articles designed to receive RFID devices thereby preventing electromagnetic access thereto. The invention further comprises a preformed electromagnetic shielding layer useful in retrofitting existing wallets, purses, and the like to protect RFID devices received therein against electromagnetic access.

### BRIEF DESCRIPTION OF THE DRAWINGS

A more complete understanding of the present invention may be had by reference to the following Detailed Description when taken in connection with the accompanying Drawings, wherein:

FIG. 1 is a perspective view of a shielding pouch comprising a first embodiment of the present invention;

FIG. 2 is a perspective view of a shielding pouch comprising an alternative closure device;

FIG. 3 is a perspective view of a shielding pouch comprising another alternative closure device;

FIG. 4 is a perspective view of a shielding pouch comprising a non-closure opening;

FIG. 5 is a perspective view of a wallet comprising a second embodiment of the invention;

FIG. 6 is an illustration of a purse comprising a third embodiment of the invention;

FIG. 7 is an illustration of an electromagnetic shielding device comprising a fourth embodiment of the invention;

FIG. 8 is an illustration of a passport receiving portfolio comprising a fifth embodiment of the invention;

FIG. 9 is an Illustration of a card holder comprising a sixth embodiment of the invention;

FIG. 10A is an illustration of a first version of a seventh embodiment of the invention;

FIG. 10B is an illustration of a second version of the seventh embodiment of the Invention;

FIG. 10C is an illustration of a third version of the seventh d embodiment of the invention;

FIG. 11 is an illustration of an eighth embodiment of the invention; and

FIG. 12 is an illustration of a ninth embodiment of the invention.

### DETAILED DESCRIPTION

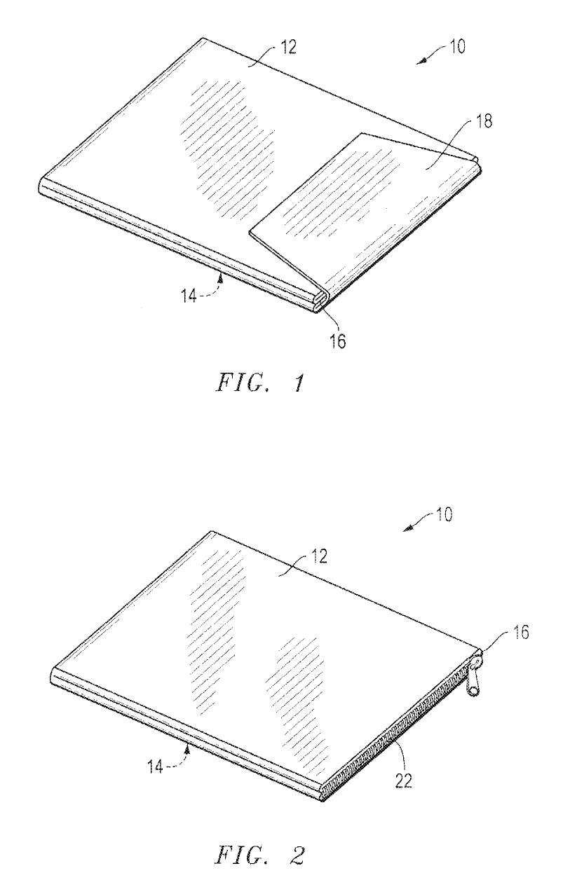

Referring now to the Drawings, and particularly to FIGS. 1 and 2 thereof, there is shown a shielding pouch 10 comprising a first embodiment of the invention. The shielding pouch comprises an upper surface 12 and a lower surface 14 which are secured together to form a compartment having an opening 16 at one end thereof for receiving items into the compartment. A flap 18 extending from the lower surface 14 folds over the opening 16 thereby closing the compartment and maintaining items received in the pouch 10 secure therein.

In the construction of the pouch 10 the upper surface 12 and lower surface 14 are formed from two pieces of material sewn together along three of the four edges thereof. Alternatively, the pouch 10 may be constructed using one solid piece of material folded over and sewn together along both sides thereof. Alternative to sewing the upper 12 and lower surface 14 together the upper 12 and lower surface 14 may be glued together or secured together by other suitable means known to those skilled in the art.

The upper surface 12 and lower surface 14 are fabricated from a textile having electromagnetic shielding incorporated therein. The upper surface 12 and lower surface 14 may also be fabricated from a lightweight polymer having electromagnetic shielding incorporated therein or any other suitable material having electromagnetic shielding incorporated therein.

FIG. 2 illustrates the pouch 10 comprising a zipper 22 extending across the opening 16 in place of the flap 16 providing an alternative closure means for the pouch 10.

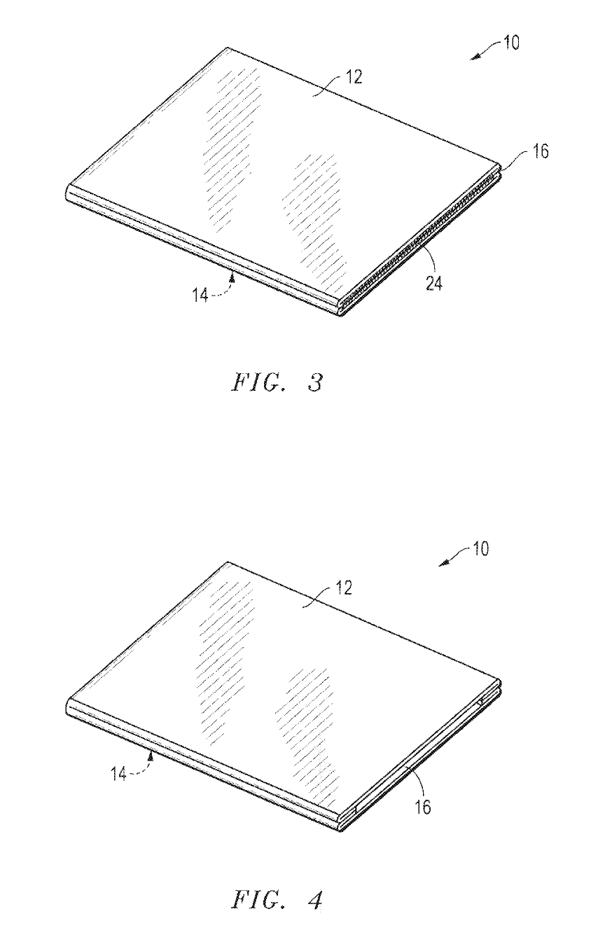

FIG. 3 illustrates the pouch 10 comprising hook-and-loop fasteners 24 commonly sold under the trademark VELCRO® providing alternative closure means for the pouch 10.

FIG. 4 illustrates the pouch 10 without any means for closing the opening 16.

The pouch 13 of the present invention as shown receives identification cards, credit cards, and similar items having RFID devices incorporated therein thereby preventing electromagnetic access to the enclosed items. The pouch is thereafter received in a wallet, handbag, or pocket for safekeeping.

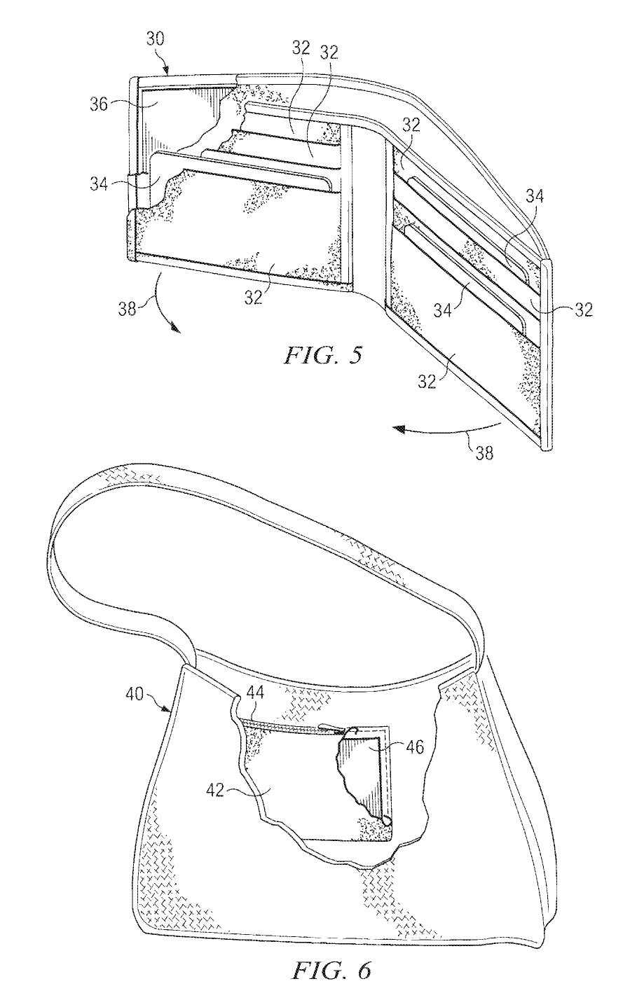

A wallet 30 comprising a second embodiment of the invention is illustrated in FIG. 5. The wallet 30 comprises a plurality of pockets 32 each for receiving a card 34. The cards 34 comprise credit cards, personal identification cards such as drivers licenses and the like, and other types and kinds of cards having RFID devices embedded therein. The wallet 30 is provided with a layer 36 comprising an electromagnetic shielding material. The layer 36 extends the entire length and width of the wallet 30 and extends behind the cards 34 when the wallet 30 is in its open configuration as illustrated in FIG. 5.

In use the wallet 30 is opened to the configuration shown in FIG. 5 to permit access to the cards 34 and other contents of the wallet 30. Thereafter the wallet is folded into a closed configuration as indicated by the arrows 38. When the wallet 30 is in its closed configuration the electromagnetic shielding layer 36 extends on both sides of the cards 34 contained in the wallet 30.

As is well known to those skilled in the art, wallets of the type illustrated in FIG. 5 are in widespread use for the transportation of credit cards, personal identification cards, currency, and other items. Wallets of the type shown in FIG. 5 are typically folded into the closed configuration and thereafter transported in a pocket or purse. When the wallet 30 is utilized for the transportation of credit cards, personal identification cards and other cards having RFID devices embedded therein the electromagnetic shielding layer 36 prevents unauthorized electromagnetic access to the RFID devices comprising the cards 34.

FIG. 6 illustrates a nurse 40 comprising a third embodiment of the invention. The purse 40 is conventional in construction with the exception of a pocket 42 mounted within the interior of the nurse 40 and adapted to receive one or more cards comprising credit cards, personal identification cards, and other cards having RFID devices embedded therein. The pocket 42 may be provided with a zipper 44 or other conventional closure device for securing cards within the pocket.

The pocket 42 is provided with a layer of electromagnetic shielding material 46. The layer of electromagnetic shielding material 46 extends the entire length and width of the pocket 42 and preferably extends the entire length and width of both sides comprising the pocket 42.

In the use of the purpose 40 one or more cards such as credit cards, personal identification cards, and other cards having RFID devices embedded therein are received in the pocket 42 and are retained therein by means of the closure device 44. The layer of electromagnetic shielding material 46 extends on both sides of the cards received in the pocket 42 thereby preventing electronic access to the RFID devices comprising the cards which are received and transported in the pocket 42 of the purse 40.

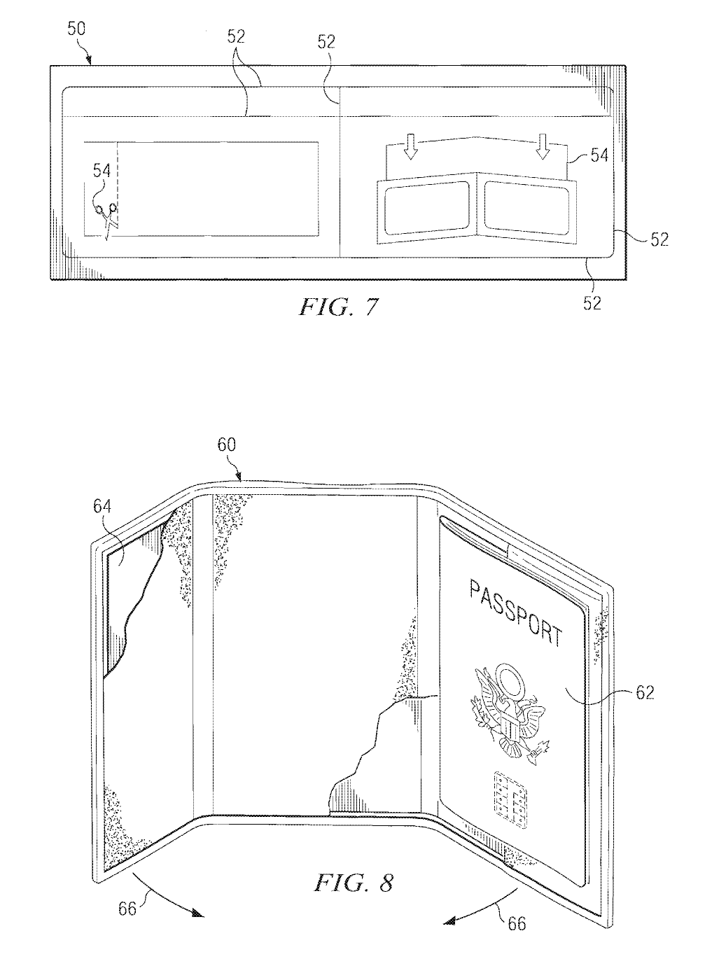

FIG. 7 illustrates a fourth embodiment of the invention comprising a layer of electromagnetic shield material 50 specifically adapted to the retrofitting of existing wallets, purses, credit card holders, and the like to provide protection against electromagnetic access to RFID devices embedded in credit cards, personal identification cards, and other cards contained and transported therein. The layer of electromagnetic shielding material 50 is intentionally provided with length and width dimensions which are larger than the corresponding dimensions of conventional wallets, purses, credit card holders, and the like. A plurality of guidance lines 52 are provided on the layer 50 to facilitate cutting of the layer 50 to a size appropriate for the use thereof in a particular wallet, purse, credit card holder or the like. The electromagnetic shielding layer 50 is further provided with indicia 54 which provide directions as to the use thereof in retrofitting an existing wallet, purse, credit card holder or the like to provide electromagnetic shielding for credit cards, personal identification cards, and other cards having REID devices embedded therein.

The wallet 80 may further comprise pockets 85 for receiving cards 86 and other items that are equipped with RFID devices. An electromagnetic shielding layer 87 similar to the layer 84 extends behind the pockets 85 and the cards 86 therein. Each pocket 85 is provided with an electromagnetic shielding layer 88 that extends in front of a card 86 received in the pocket 85.

A passport receiving portfolio 60 comprising a fifth embodiment of the invention is illustrated in FIG. 8. The portfolio 60 is specifically designed and intended to receive and transport a passport 62 therein. The portfolio 60 may also be used to transport other documents. Additionally, the portfolio 60 may be utilized to receive and transport credit cards, personal identification cards, and other cards having RFID devices embedded therein.

As is well known to those skilled in the art, United States passports and passports issued by other countries will Soon) have RFID devices embedded therein. The function of the portfolio 60 is to protect the passport 62 against unauthorized electronic access to the RFID device embedded therein.

The portfolio 60 is provided with a layer of electromagnet-c shielding material 64 which extends the entire length and width of the portfolio 60. The portfolio 60 is illustrated in its open configuration which allows access to the passport 62 and other contents of the portfolio 60. The portfolio 60 is normally folded inwardly as indicated by the arrows 66. When the portfolio 60 is in ins folded configuration the layer of electromagnetic shielding material 64 extends on both sides of the passport 62 and other contents of the portfolio 60 thereby preventing unauthorized electronic access to the RFID device embedded within the passport 62 and further preventing electronic access to any other RFID devices embedded in objects contained within the portfolio 60.

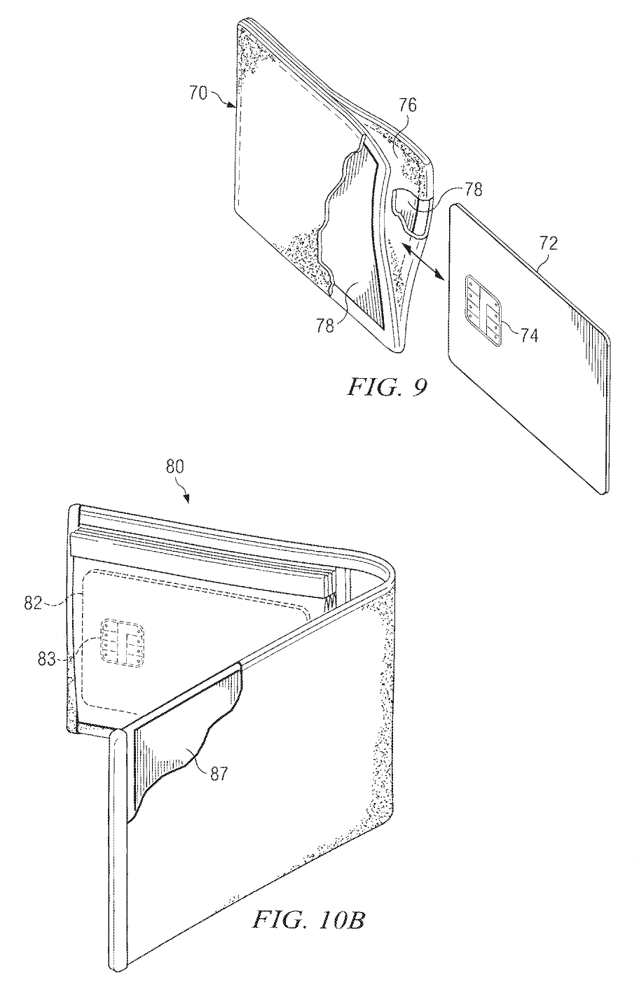

A card holder 70 comprising a sixth embodiment of the invention is illustrated in FIG. 9. The card holder 70 is adapted to receive and transport a card 72 having an REID device 74 embedded therein. The card 72 may comprise a credit card, a personal identification card such as a drivers license or the like, or any other type of card having an RFID device embedded therein.

In most respects the card holder 70 is conventional in design and comprises a pocket 76 for receiving one or more cards 72 having REID devices 74 embedded therein. The card holder 70 differs from prior card holder designs in that it is provided with layers of electromagnetic shield materials 78 extending on both sides of the pocket 76 and therefore extending on both sides of one or more cards 72 that are received in the pocket 76. The layers of electromagnetic shielding material 78 prevent unauthorized electronic access to RFID devices 74 embedded within the card or cards 72 received in the card holder 70 for transportation and storage therein.

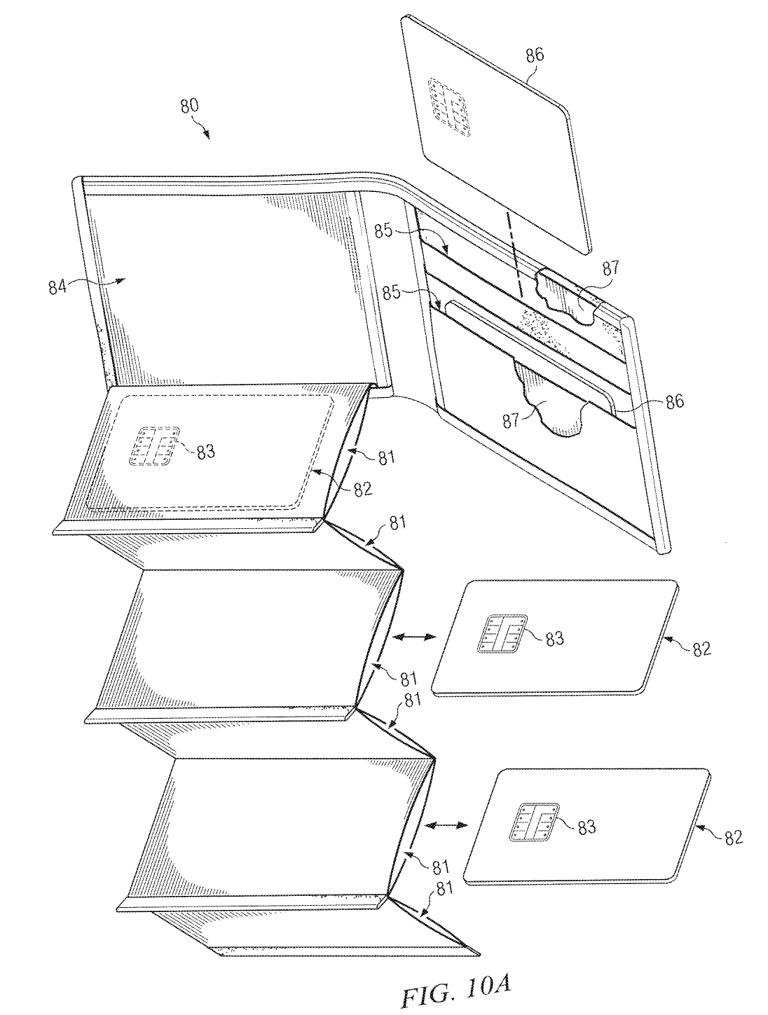

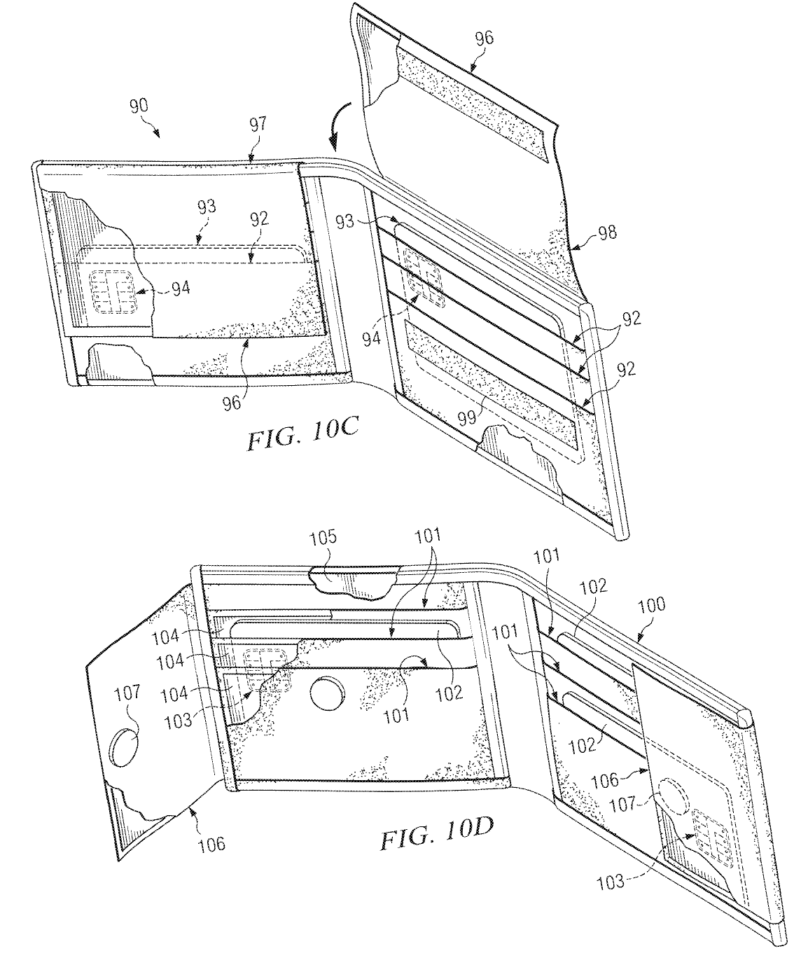

A wallet 80 comprising a first version of the a seventh embodiment of the invention is illustrated in FIG. 10A. The wallet 80 comprises a plurality of pockets 81 each for receiving a card 82 such as a credit card, a personal identification card, etc. having an RFID device 83 embedded therein. The pockets 81 may be constructed entirely from an electromagnetic shield material. Alternatively, the pockets 81 may be constructed from materials of the type conventionally used in wallet construction which are lined with layers of electromagnetic shielding material. An electromagnetic shielding layer 84 extends behind the pockets 81 to provide additional shielding.

Referring to FIG. 10B there is shown a wallet 90 comprising a second version of the seventh embodiment of the invention. The wallet 90 comprises a plurality of pockets 92 each for receiving a card 93 such as a credit card, a personal identification card, etc. having an REID device 94 embedded therein. The wallet 90 further comprises flaps 96 which may be constructed entirely from an electromagnetic shield material. Alternatively, the flaps 96 may be constructed from materials of the type commonly used in wallet construction which are lined with layers of electromagnetic shield material. The flaps 96 may be secured to an interior surface as indicated at 97 or alternatively, the flaps 96 may be secured to an exterior surface as indicated at 98. The flaps 96 may be secured in place by hook-and-loop type fasteners as indicated at 99 or by other securing techniques commonly used in the manufacture of wallets and similar devices.

A wallet 100 comprising a third version of the seventh embodiment of the invention is illustrated in FIG. 10C. The left hand side (FIG. 100) of the wallet 100 comprises a plurality of pockets 101 each, for receiving a card 102 such as a credit card, a personal identification card, etc. having an RFID device 103 embedded therein. Each of the pockets 101 has a layer of electromagnetic shield material 104 on the interior surface thereof which protects the RFID devices 103 of the cards 102 from unauthorized access. The cards 102 are further protected by a layer of electromagnetic shielding material 105 which extends behind the pockets 101. The cards 102 are further protected by a flap 106 formed from or including a layer of electromagnetic shielding material. The flap 106 is normally retained in its closed configuration by a fastener 107.

The right hand side (FIG. 10C) of the wallet 100 also comprises pockets 101 each for receiving a card 102 such as a credit card, a personal identification card, etc. having an RFID device 103 embedded therein. The right hand side (FIG. 10C) of the wallet 100 further includes a flap 106 formed from electromagnetic shielding material which guards the RFID device 103 against unauthorized access. The flap 106 may be secured in place by a snap or other conventional pocket fastener 107.

As will be appreciated by those skilled in the art the various features and components comprising the first, second, and third versions of the seventh embodiment of the invention may be exchanged and intermingled with one another in order to provide a wallet configured to provide electromagnetic shielding for whatever RFID devices are intended to be contained therein. By way of example, the pockets 86 of the wallet 80 illustrated in FIG. 10A may be provided with electromagnetic shielding layers similar to the electromagnetic shielding layers 96 illustrated in FIG. 10B or the electromagnetic shielding layers 104 and 106 illustrated in FIG. 10C. Other rearrangements and adaptations of the components comprising the three versions of the seventh embodiment of the invention will readily suggest themselves to one skilled in the art.

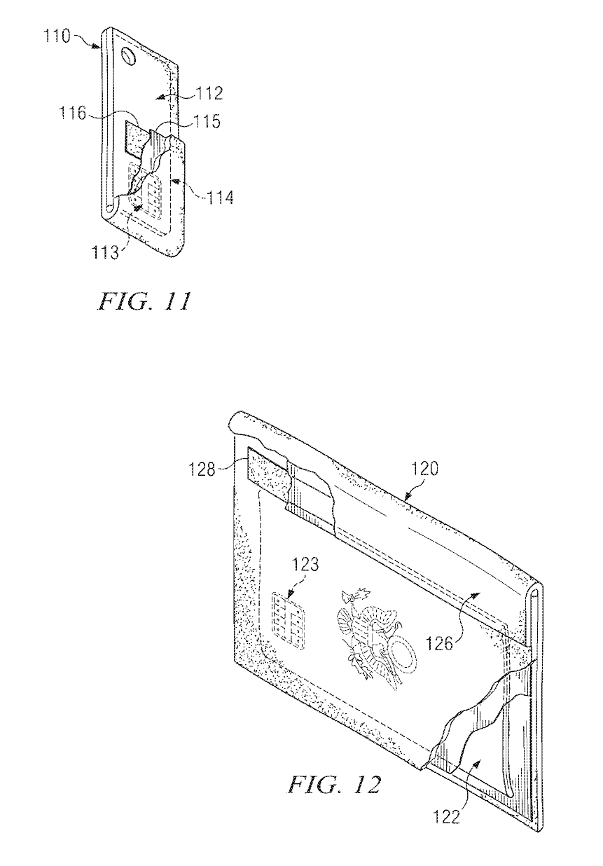

A protective shielding case 110 for a key fob 112 having an RFID device 113 embedded therein comprising an eighth embodiment of the invention is illustrated in FIG. 11. The protective case 110 comprises an outer shell 114 formed from natural materials such as leather; etc. and/or synthetic materials such as various plastics as illustrated in FIG. 11. The shell 114 is provided with a layer 115 comprising an electromagnetic shielding material. The layer of electromagnetic shielding material protects the RFID device 113 from unauthorized access. The device 110 is normally retained in a closed configuration by means of a conventional fastening device 116 such as a hook-and-loop type fastener.

A passport wallet 120 comprising a ninth embodiment of the invention is illustrated in FIG. 12. The wallet 120 receives a passport 122 having an RFID device 123 embedded therein.

The passport wallet 120 may be constructed entirely from electromagnetic shielding material. Alternatively, the passport wallet 120 may be constructed from conventional materials provided that a layer of electromagnetic shielding material is provided on the interior surfaces thereof and extends on both sides of the passport 122 thereby protecting the RFID device 123 against unauthorized access. The wallet 120 may be provided with a closure flap 126 which is normally secured in its closed configuration by conventional closure means such as a hook-and-loop type fastener, one or more snaps, a zipper, etc.

As will be appreciated by those skilled in the art, the embodiment of the invention shown in FIG. 12 can be constructed in a variety of sizes to accommodate a variety of RFID-containing devices therein. Specifically, the embodiment of FIG. 12 can be configured to receive and protect RFID device containing credit cards.

Although preferred embodiments of the invention have been illustrated in the accompanying Drawings and described in the foregoing Detailed Description, it will be understood that the invention is not limited to the embodiments disclosed, but is capable of numerous rearrangements, modifications, and substitutions of parts and elements without departing from the spirit of the invention.

1. A method of preventing unauthorized electromagnetic access to an RFID device embedded within a card comprising the steps of:
providing at least one length of electromagnetic shielding material; and
substantially surrounding the card having the RFID device embedded therein with the length of electromagnetic shielding material.

2. An apparatus or preventing unauthorized electronic access to an RFID device embedded within a card comprising:
at least one length of electromagnetic shielding material; and
means for positioning the length of electromagnetic shielding material in a surrounding relationship with respect to the card having the RFID device embedded therein.
